(19) United States
(12) Patent Application Publication
(10) Pub. No.: US 2023/0024104 A1
(43) Pub. Date: Jan. 26, 2023

(54) IDENTIFICATION OF FALSE TRANSFORMER HUMMING USING MACHINE LEARNING

(71) Applicant: NEC Laboratories America, Inc., Princeton, NJ (US)

(72) Inventors: Yangmin DING, North Brunswick, NJ (US); Sarper OZHARAR, Princeton, NJ (US); Yue TIAN, Princeton, NJ (US); Ting WANG, West Windsor, NY (US)

(73) Assignee: NEC LABORATORIES AMERICA, INC, Princeton, NJ (US)

(21) Appl. No.: 17/871,862

(22) Filed: Jul. 22, 2022

Related U.S. Application Data
(60) Provisional application No. 63/224,934, filed on Jul. 23, 2021.

(51) Int. Cl. G01R 31/62; G01H 9/00

(52) U.S. Cl. CPC G01R 31/62; G01H 9/004

(57) ABSTRACT

Systems, and methods for automatically determining false transformer humming when using DFOS systems and methods to determine such humming along with machine learning approach(es) to identify the false transformer humming signal(s) that are transferred to a utility pole without a transformer from a working transformer on another utility pole. Advantageously, our inventive systems and methods employ a customized signal processing workflow to process raw data collected from the DFOS. Our employs a binary classifier that can automatically identify a transformer humming signal from a utility pole with a transformer and simultaneously identify the false humming signal from a utility pole without a transformer.

### CROSS REFERENCE TO RELATED APPLCIATIONS

This application claims the benefit of U.S. Provisional Patent Application Ser. No. 63/224,934 filed 23Jul. 2021 the entire contents of which is incorporated by reference as if set forth at length herein.

### TECHNICAL FIELD

This disclosure relates generally to optical fiber telecommunications facilities and distributed fiber optic sensing (DFOS) over same. More particularly, it describes systems and methods for the identification of false transformer humming using DFOS and machine learning.

### BACKGROUND

Distributed fiber optic sensing (DFOS) systems and methods transform existing optical telecommunications cable(s) and facilities into distributed sensors that enable real-time continuous data collection. By detecting humming sound frequencies (120 Hz and its integer harmonics) of an electrical transmission/distribution system transformer using DFOS it is possible to monitor a transformer's health status. However, transformer hum is generally caused by an expansion and contraction of core laminations when magnetized and is strong enough to transfer vibrations to utility poles without a transformer. As a result, the humming frequency and its harmonics will appear on a utility poles without transformers when DFOS data is collected, which results in a false diagnosis of transformer health based on the humming signal(s).

### SUMMARY

An advance in the art is made according to aspects of the present disclosure directed to systems, and methods for automatically determining false transformer humming when using DFOS systems and methods to determine such humming. In sharp contrast to the prior art, systems and methods according to the present disclosure utilize machine learning approach(es) to identify the false transformer humming signal(s) that are transferred to a utility pole without a transformer from a working transformer on another utility pole. Advantageously, our inventive systems and methods employ a customized signal processing workflow to process raw data collected from the DFOS.

More particularly, our inventive method according to aspects of the present disclosure employs a binary classifier that can automatically identify a transformer humming signal from a utility pole with a transformer and simultaneously identify the false humming signal from a utility pole without a transformer. As a result, the ability to provide automatic transformer health monitoring based on vibration or humming of a transformer is realized while eliminating uncertainties that plague the art.

### BRIEF DESCRIPTION OF THE DRAWING

A more complete understanding of the present disclosure may be realized by reference to the accompanying drawing in which:

FIG. 1 is a schematic diagram of an illustrative distributed fiber optic sensing system according to aspects of the present disclosure;

FIG. 2(A) is a schematic diagram illustrating a transformer vibration transferred between utility poles according to aspects of the present disclosure;

FIG. 2(B) is a plot illustrating humming of a utility pole with a transformer according to aspects of the present disclosure;

FIG. 2(C) is a plot illustrating humming of a utility pole without a transformer according to aspects of the present disclosure;

FIG. 3(A) is a schematic flow diagram illustrating training processes according to aspects of the present disclosure;

FIG. 3(B) is a schematic flow diagram illustrating predicting processes according to aspects of the present disclosure;

FIG. 4 is a schematic diagram illustrating data segmentation and down-sampling according to aspects of the present disclosure;

FIG. 5(A) is a plot illustrating an example of an average of segmented data with band-pass filtering for a utility pole with transformer according to aspects of the present disclosure;

FIG. 5(B) is a plot illustrating an example of an average of segmented data with band-pass filtering for a utility pole without transformer according to aspects of the present disclosure;

FIG. 6 is a schematic diagram illustrating principal component analysis (PCA) with 6 features or sensor node from distributed acoustic sensing according to aspects of the present disclosure;

FIG. 7 (A) and FIG. 7(B) are plots illustrating PCA results with different segmentation lengths according to aspects of the present disclosure;

FIG. 8 (A)-FIG. 8(C) are plots illustrating a training example for C=30 and FIG. 8 (D)-FIG. 8(F) are plots illustrating a training example for C=100 according to aspects of the present disclosure; and

FIG. 9(A)-FIG. 9(O) is a schematic diagram illustrating confusion matrices of SVM using averaged PCA on a segmented time series data set according to aspects of the present disclosure.

The illustrative embodiments are described more fully by the Figures and detailed description. Embodiments according to this disclosure may, however, be embodied in various forms and are not limited to specific or illustrative embodiments described in the drawing and detailed description.

### DESCRIPTION

The following merely illustrates the principles of the disclosure. It will thus be appreciated that those skilled in the art will be able to devise various arrangements which, although not explicitly described or shown herein, embody the principles of the disclosure and are included within its spirit and scope.

Furthermore, all examples and conditional language recited herein are intended to be only for pedagogical purposes to aid the reader in understanding the principles of the disclosure and the concepts contributed by the inventor(s) to furthering the art and are to be construed as being without limitation to such specifically recited examples and conditions.

Moreover, all statements herein reciting principles, aspects, and embodiments of the disclosure, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

Thus, for example, it will be appreciated by those skilled in the art that any block diagrams herein represent conceptual views of illustrative circuitry embodying the principles of the disclosure.

Unless otherwise explicitly specified herein, the FIGs comprising the drawing are not drawn to scale.

By way of some additional background, we note that distributed fiber optic sensing systems interconnect opto-electronic integrators to an optical fiber (or cable), converting the fiber to an array of sensors distributed along the length of the fiber. In effect, the fiber becomes a sensor, while the interrogator generates/injects laser light energy into the fiber and senses/detects events along the fiber length.

As those skilled in the art will understand and appreciate, DFOS technology can be deployed to continuously monitor vehicle movement, human traffic, excavating activity, seismic activity, temperatures, structural integrity, liquid and gas leaks, and many other conditions and activities. It is used around the world to monitor power stations, telecom networks, railways, roads, bridges, international borders, critical infrastructure, terrestrial and subsea power and pipelines, and downhole applications in oil, gas, and enhanced geothermal electricity generation. Advantageously, distributed fiber optic sensing is not constrained by line of sight or remote power access and—depending on system configuration—can be deployed in continuous lengths exceeding 30 miles with sensing/detection at every point along its length. As such, cost per sensing point over great distances typically cannot be matched by competing technologies.

Fiber optic sensing measures changes in “backscattering” of light occurring in an optical sensing fiber when the sensing fiber encounters vibration, strain, or temperature change events. As noted, the sensing fiber serves as sensor over its entire length, delivering real time information on physical/environmental surroundings, and fiber integrity/security. Furthermore, distributed fiber optic sensing data pinpoints a precise location of events and conditions occurring at or near the sensing fiber.

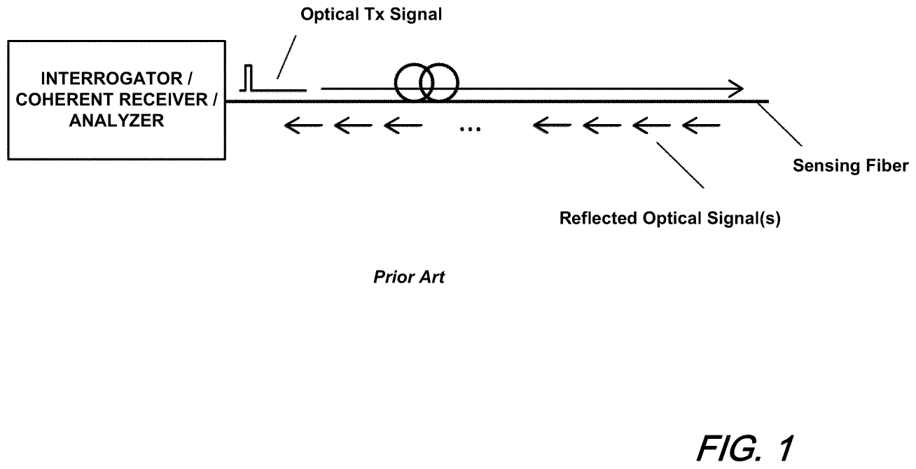

A schematic diagram illustrating the generalized arrangement and operation of a distributed fiber optic sensing system including artificial intelligence analysis and cloud storage/service is shown in FIG. 1. With reference to FIG. 1 one may observe an optical sensing fiber that in turn is connected to an interrogator. As is known, contemporary interrogators are systems that generate an input signal to the fiber and detects/analyzes reflected/scattered and subsequently received signal(s). The signals are analyzed, and an output is generated which is indicative of the environmental conditions encountered along the length of the fiber. The signal(s) so received may result from reflections in the fiber, such as Raman backscattering, Rayleigh backscattering, and Brillion backscattering. It can also be a signal of forward direction that uses the speed difference of multiple modes. Without losing generality, the following description assumes reflected signal though the same approaches can be applied to forwarded signal as well.

As will be appreciated, a contemporary DFOS system includes the interrogator that periodically generates optical pulses (or any coded signal) and injects them into an optical fiber. The injected optical pulse signal is conveyed along the optical fiber.

At locations along the length of the fiber, a small portion of signal is scattered/reflected and conveyed back to the interrogator. The scattered/reflected signal carries information the interrogator uses to detect, such as a power level change that indicates—for example—a mechanical vibration.

The reflected signal is converted to electrical domain and processed inside the interrogator. Based on the pulse injection time and the time signal is detected, the interrogator determines at which location along the fiber the signal is coming from, thus able to sense the activity of each location along the fiber.

Distributed Acoustic Sensing (DAS)/Distributed Vibrational Sensing (DVS) systems detect vibrations and capture acoustic energy along the length of optical sensing fiber. Advantageously, existing, traffic carrying fiber optic networks may be utilized and turned into a distributed acoustic sensor, capturing real lime data. Classification algorithms may be thither used to detect and locate events such as leaks, cable faults, intrusion activities, or other abnormal events including both acoustic and/or vibrational.

Various DAS/DVS technologies are presently used with the most common being based on Coherent Optical Time Domain Reflectometry (C-OTDR). C-OTDR utilizes sigh back-scattering, allowing acoustic frequency signals to be detected over long distances. An interrogator sends a coherent laser puke along, the length of an optical sensor fiber (cable). Scattering sites within the fiber cause the fiber to act as a distributed interferometer with a gauge length like that of the pulse length (e.g. 10 meters). Acoustic/mechanical disturbance acting on the sensor fiber generates microscopic elongation or compression of the fiber (micro-strain), which causes a change in the phase relation and/or amplitude of the light pulses traversing therein.

Before a next laser puke is be transmitted, a previous pulse must have had time to travel the full length of the sensing fiber and for its scattering/reflections to return. Hence the maximum pulse rate is determined by the length of the fiber. Therefore, acoustic signals can be measured that vary at frequencies up to the Nyquist frequency, which is typically half of the pulse rate. As higher frequencies are attenuated very quickly, most of the relevant ones to detect and classify events are in the lower of the 2 kHz range.

As we shall show and describe and as already noted, our inventive systems and methods automatically detect/interpret vibration signals resulting from DFOS operation using deployed fiber optic sensor cables to detect/locate cable vibrations caused by—for example—humming of transformers that are suspended from utility poles operating sufficiently proximate to the deployed fiber optic sensor cable.

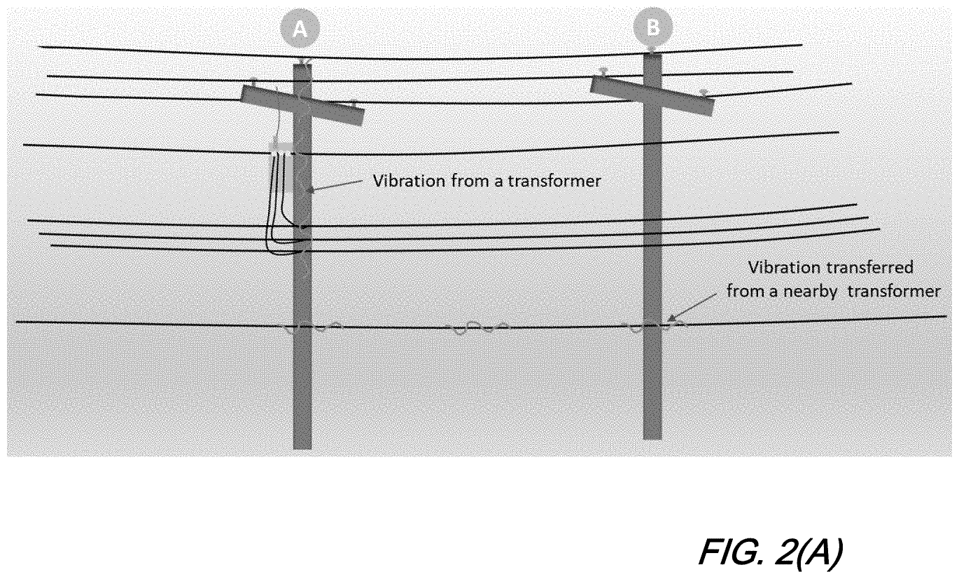

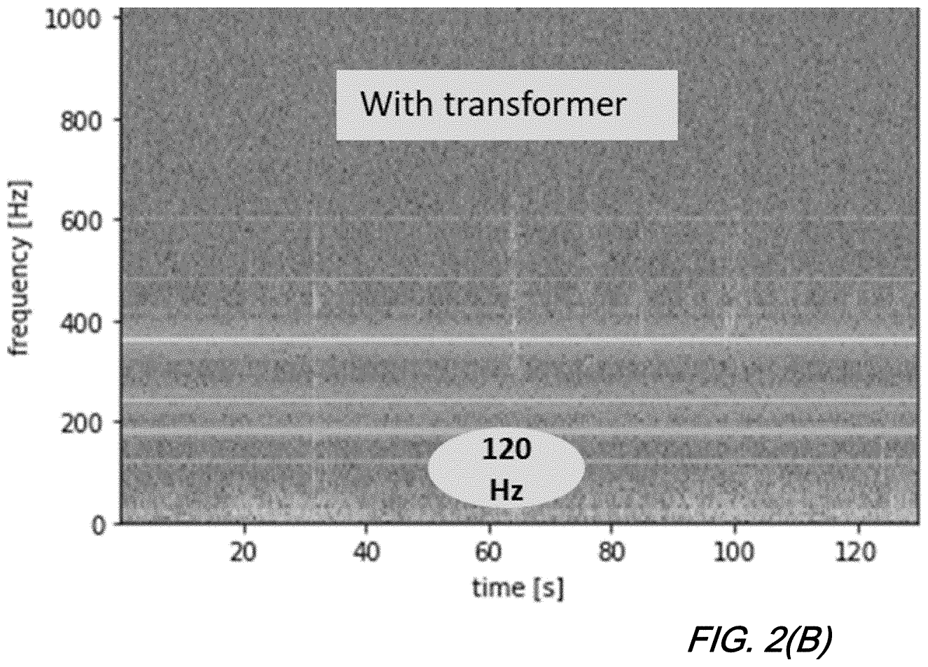

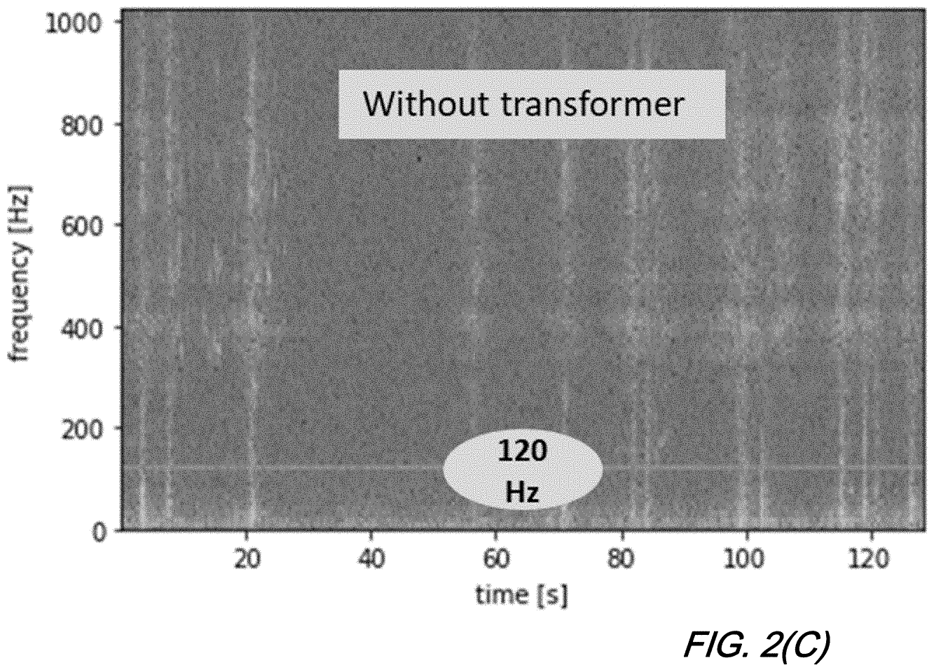

FIG. 2(A) is a schematic diagram illustrating a transformer vibration transferred between utility poles according to aspects of the present disclosure. As may be observed from that figure—and as previously noted—transformer humming vibrations not only affect a utility pole to which they are suspended, they also affect utility poles that are sufficiently proximate thereby making location determination of a humming transformer difficult using DFOS/DVS techniques.

FIG. 2(B) is a plot illustrating humming of a utility pole with a transformer according to aspects of the present disclosure and FIG. 2(C) is a plot illustrating humming of a utility pole without a transformer according to aspects of the present disclosure. The plots are short-time Fourier transform (STFT) results from sensor data collected from two poles, respectively with a transformer and without a transformer. As such, it is critical to identify a real hum vibration source for transformer health monitoring.

As we shall further describe, illustrative features of systems and methods according to aspects of the present disclosure include customized signal processing workflow and a unique classifier based on principal component analysis (PCA) and support vector machine (SVM).

Operationally, we preprocess data by apply segmentation to split a long scaled signal into smaller pieces. After segmentation, we downsample the segmented data, which improves computational efficiency for training the classifier. We also apply PCA to reduce the feature set.

Preprocess Data

For example, assume that S is the number of segmented data, N is the sample points, and K is the number of features. By doing PCA, K will be reduced to P which is P<or =K; the data set will be S×N×P after PCA. Then we average the results of PCA, which generates the N×P data set. These N×P data are split into training and testing for the Support Vector Machine (SVM).

SVM Implementation

After PCA, features are converted so that features that have maximum variance will be placed in the first few columns of the data set. A radial basis function (RBF) kernel is used for the problem to be solved in this invention due to the classifier training speed and the feature data set complexity. Multiples confusion matrix using the different number of spaces is included so that the difference of the SVM performances among various dimensional spaces can be differentiated

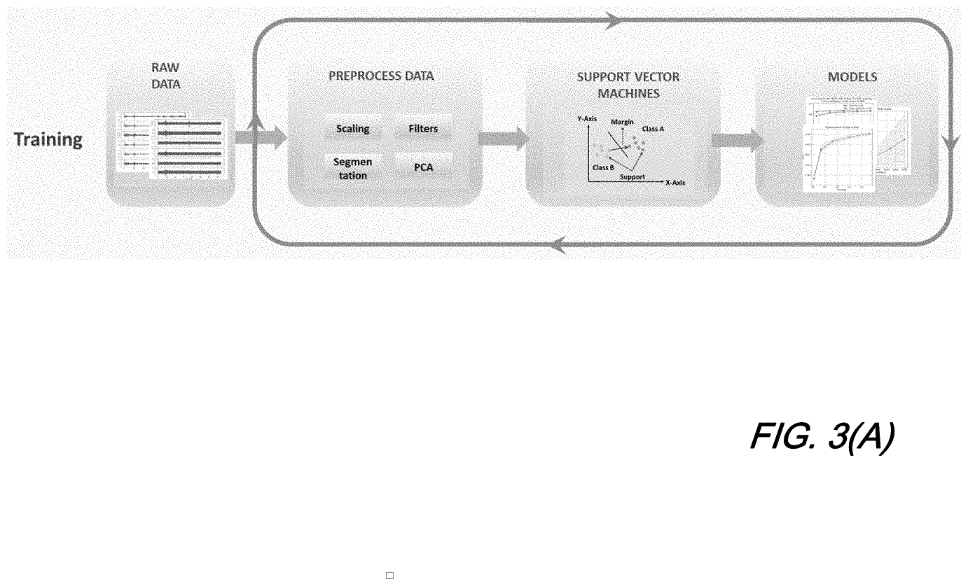

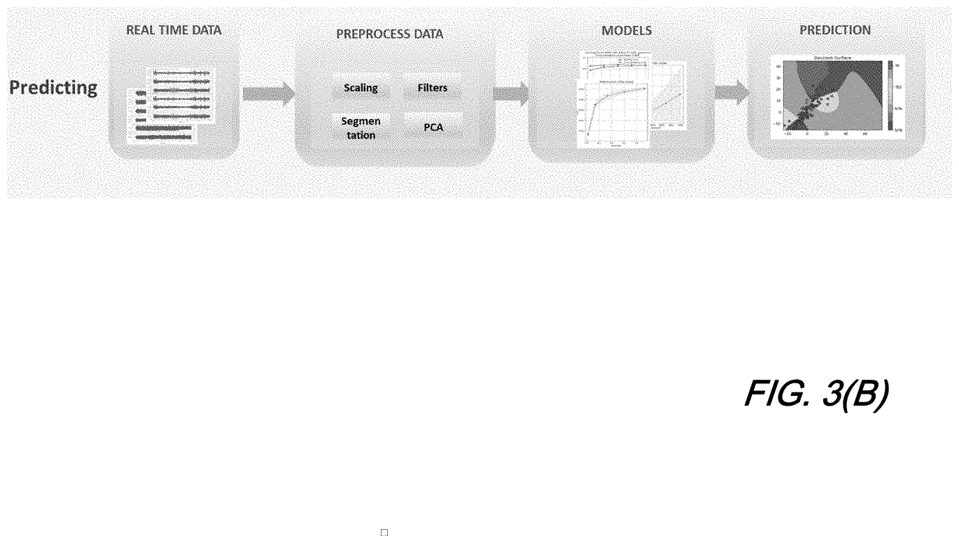

FIG. 3(A) is a schematic flow diagram illustrating training processes according to aspects of the present disclosure and FIG. 3(B) is a schematic flow diagram illustrating predicting processes according to aspects of the present disclosure.

With reference to those figures we can identify the following steps of our inventive methods.

Step 1. Data Scaling and Standardization:

Scaling data: The amplitude of the time-series signal is varied among different data sources. Thus, min-max normalization using the following equation is applied to convert raw data to have the range of 0 and 1:

$$\frac{x - minimum}{maximum - minimum}$$

Standardization: The raw data points are standardized using the following equation which converts data to have zero mean μ and σ:

$$\frac{x - μ}{σ}$$

Step 2. Butter-Worth Band-Pass Filters

Multiple bandpass filters (BPF) are applied to get the signal at the center frequency f₀ of 30 n Hz where n=1; 2; 3. The lower cutoff frequency f_{L} and higher cutoff frequency f_{H} are set to f₀+5 Hz and f₀+5 Hz, respectively.

Step 3. Segmentation:

Segmentation is a technique to split the long signal into smaller pieces. For example, the original data sets contain 2-3 minutes of data for each pole type, and they can be split into 5 second long signals with 30% overlapping.

Step 4. Down-Sampling:

The time-series raw data usually contains large numbers of data points even though segmentation is performed, which will consume more time to train the classifier.

Thus it is necessary to downsample and segment the data.

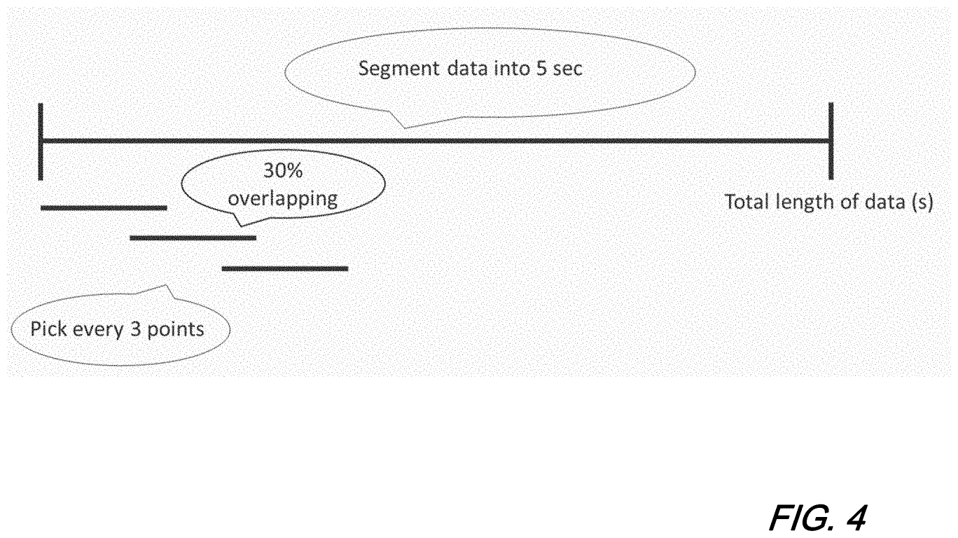

FIG. 4 is a schematic diagram illustrating data segmentation and down-sampling according to aspects of the present disclosure.

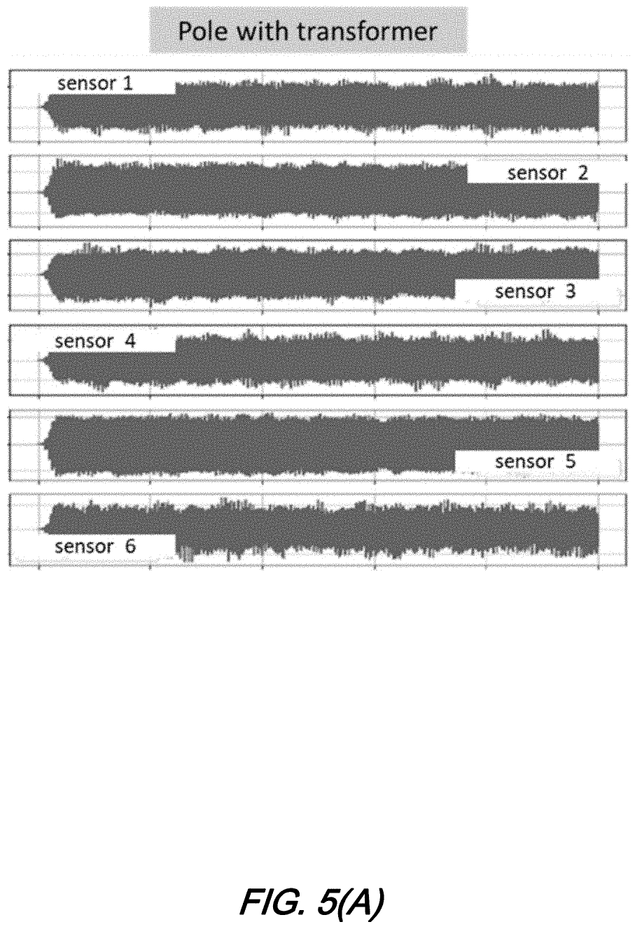

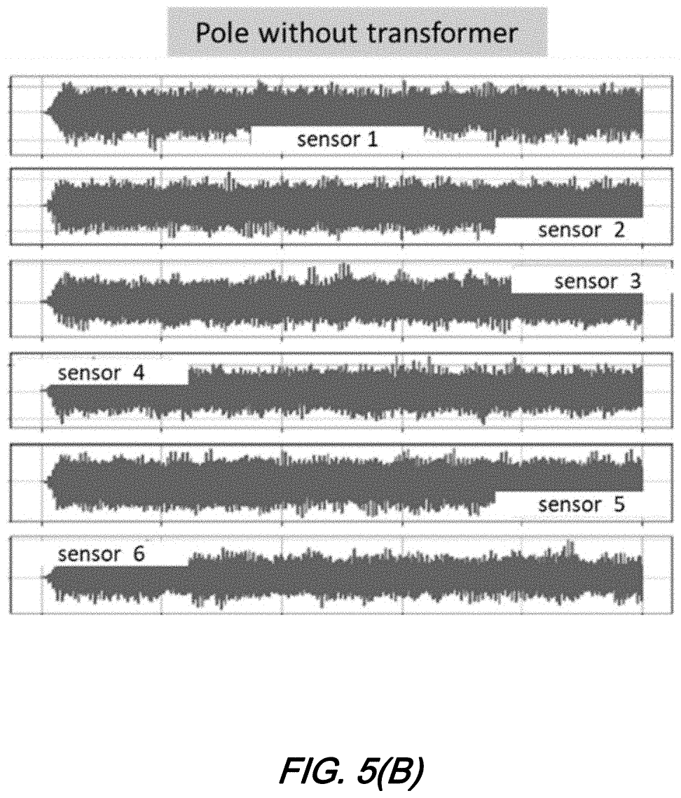

FIG. 5(A) is a plot illustrating an example of an average of segmented data with band-pass filtering for a utility pole with transformer according to aspects of the present disclosure. FIG. 5(B) is a plot illustrating an example of an average of segmented data with band-pass filtering for a utility pole without transformer according to aspects of the present disclosure. These figures illustrate an example of an average of segmented data with band-pass filtering for the data collected (6 sensor points were picked up from the pole in this example) from a pole with a transformer and a pole without a transformer. The segmentation is applied to the time-series data. Filters are applied for each segmented data

Step 5. Principal Component Analysis

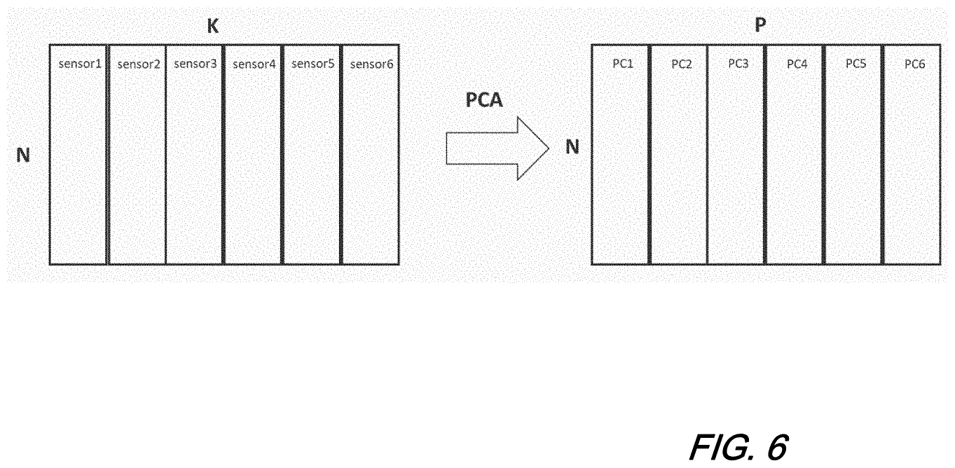

After segmentation is performed, the data matrix of dimension S×N×K, where S is the number of segmented slices, N is the number of data samples, and K is the number of features, is constructed. Features are the number of sensors on the pole in this case. PCA is applied on each segmented data in the time domain, and the average is computed which generates a matrix of dimension N×P. FIG. 6 presents an example of the PCA process in according to aspects of the present disclosure with a total of 6 sensing points. FIG. 6 is a schematic diagram illustrating principal component analysis (PCA) with 6 features or sensor node from distributed acoustic sensing according to aspects of the present disclosure.

PCA is implemented in this invention to convert data sets from the feature spaces into the reduced space. The transformed data is denoted as a matrix Z of dimension N×P where P is the number of principal components that is smaller than K. This matrix Z maximizes the variance of the original data.

To explore if the segmentation length has any effect on PCA results, different segmentation lengths of 2, 4, 6, 8, and 10 seconds are performed. Multiple band-pass filters are applied for all segmented signals. The orientation is slightly changed as the longer length is used. It also shows that the data points, especially those collected from the pole without “ real” transformers, are slightly spread out when 10 s is set. Regarding the small difference between different segmentation lengths and computation efficiency, we choose 5 s segmentation analysis for the SVM classifier.

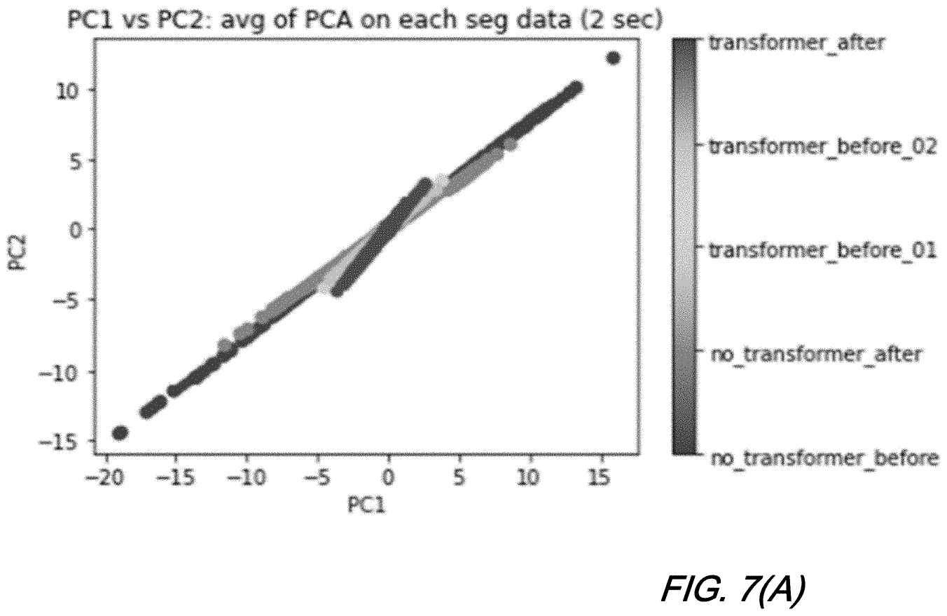

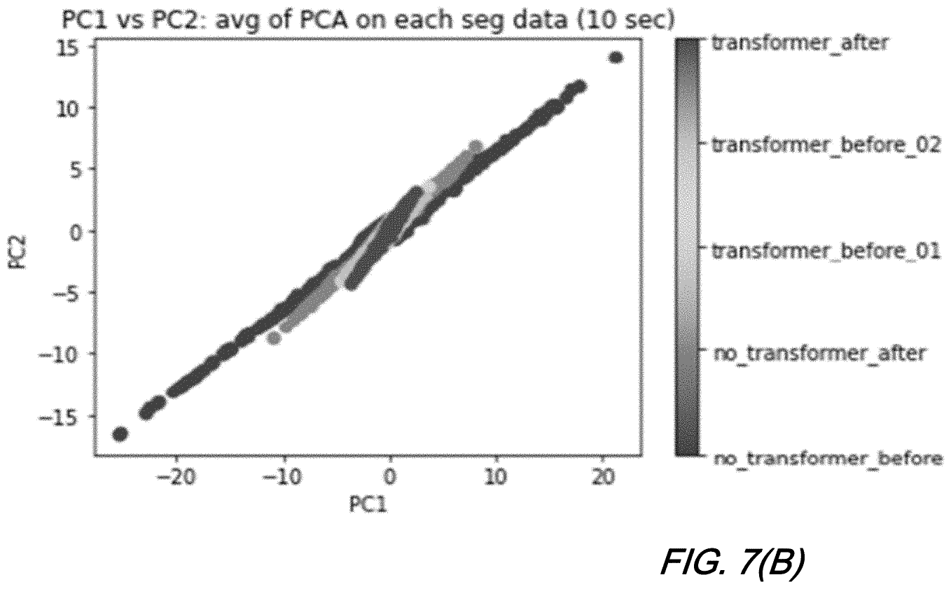

FIG. 7 (A) and FIG. 7(B) are plots illustrating PCA results with different segmentation lengths according to aspects of the present disclosure.

Step 6 Classification with Support Vector Machines

In this step, the SVM classifier is used to classify data files. The averaged PCA of segmented time-series data down-sampled by 3 with the segmentation length of 5 seconds is used. The SVM is trained and tested to classify the following classes: a pole with and without a transformer before and after street lights are on.

SVM is used with a kernel function such as a linear kernel and polynomial kernels. A radial basis function (RBF) kernel is found to be the best kernel for the problem to be solved in this invention due to the classifier training speed and the feature data set complexity. To optimize the parameters, learning curves are plotted to show the performance of the classifier as the number of training samples are increases. The confusion matrix is also plotted to determine the performance of the trained classifier using the testing data set. Additionally, the decision surface is used to visualize how the SVM classifier differentiates sample points in 2-dimensional space.

Multiple learning curves are plotted using various values of the parameters C and γ to optimize. Also, the number of required principal components to train the classifier is determined. This value, which is the columns of the input variables, corresponds to the number of dimensional spaces. For each set of figures, multiple plots are generated to show the learning curve, required training time, and the performance of the model for various.

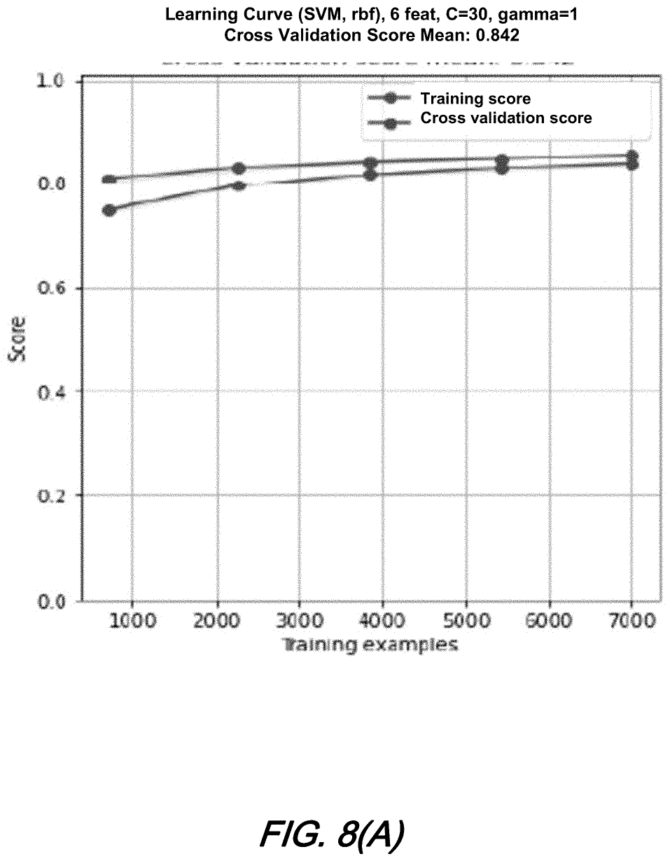

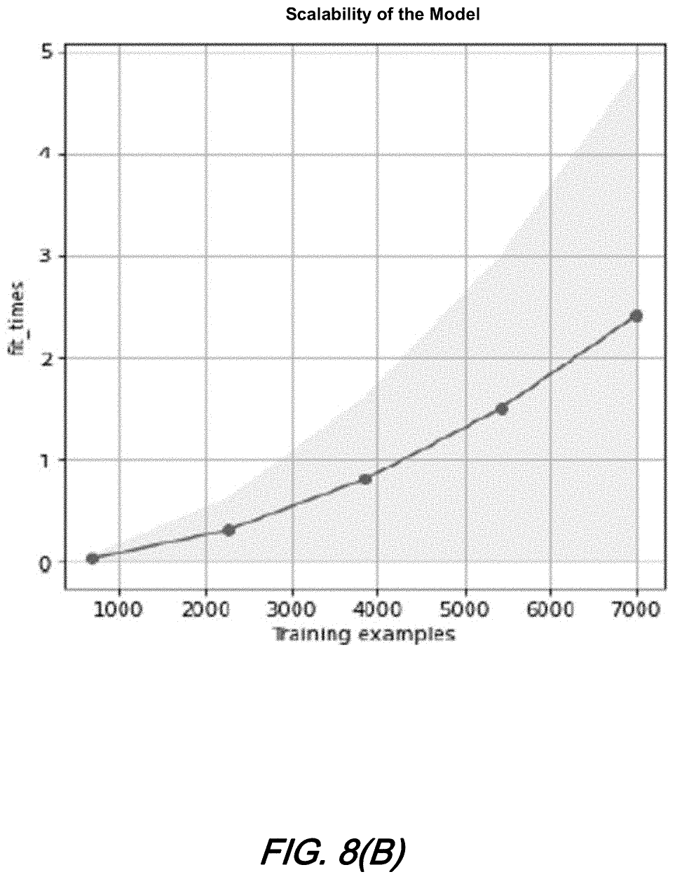

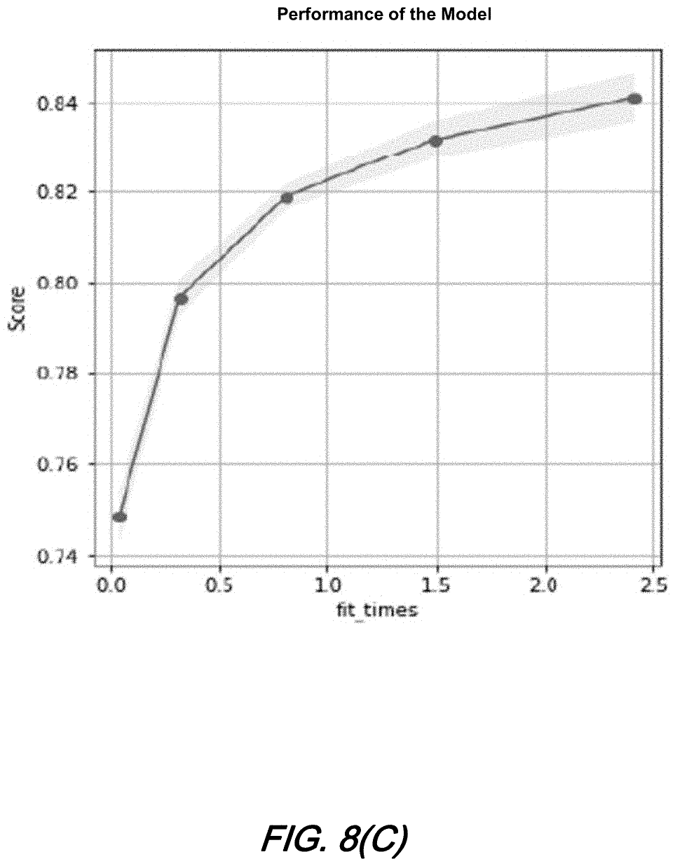

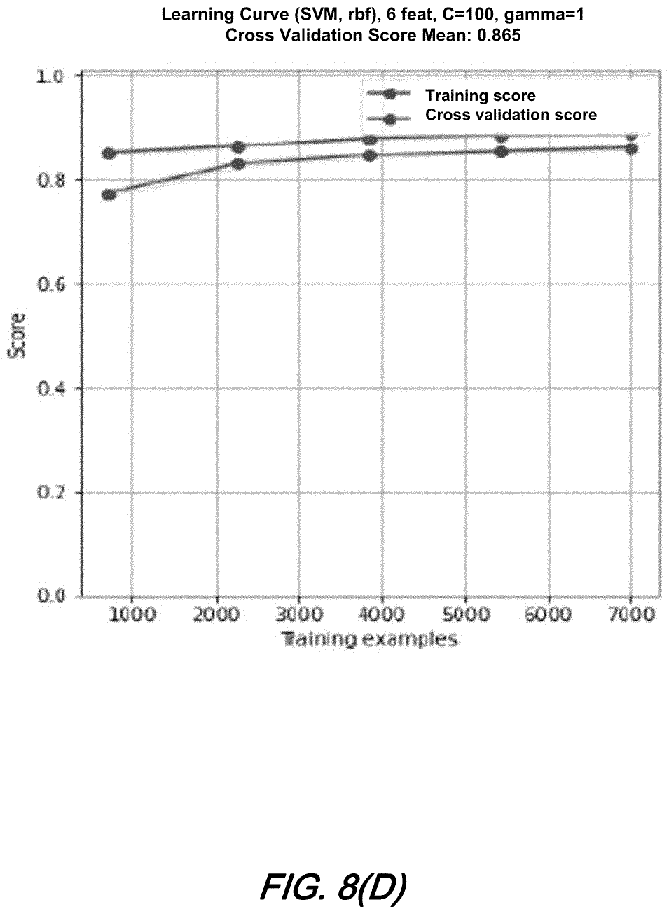

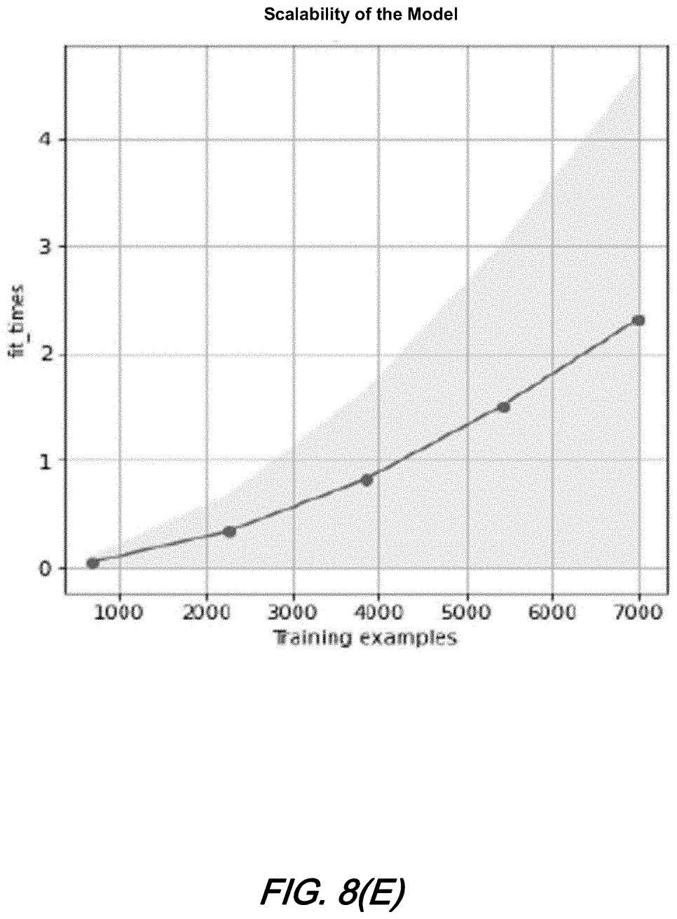

FIG. 8 (A)-FIG. 8(C) are plots illustrating a training example for C=30 and FIG. 8 (D)-FIG. 8(F) are plots illustrating a training example for C=100 according to aspects of the present disclosure. The examples presented in this figure are examples using the average of PCA on segmented time-series data down-sampled by 3 as shown in FIG. 7(A) and FIG. 7(B) with 6-dimensional spaces instead of 2-d. Each row corresponds to different C values while y is set to the value of 1. The 5-fold cross-validation is used, and its mean score is shown in the title. As we can see from the figures, increasing the C value slightly improves the performance.

Generation of confusion matrix: multiple confusion matrices are generated to compare the performance of various model parameters. The x-axis shows the predicted labels while the y-axis contains the true labels. The number of correct and wrong predictions made by the classifier is summarized in the confusion matrix. The diagonal colored with darker blue means the model can classify the classes accurately. A 7:3 split is chosen to generate a training and testing set from the feature data set. Each column corresponds to different C values, and each row corresponds to various dimensional space is formed by the input variables. The accuracy of 85-86% is achieved when the classifier is trained using feature sets constructed from the averaged PCA of time-series down-sampled segmented data.

FIG. 9(A)-FIG. 9(O) is a schematic diagram illustrating confusion matrices of SVM using averaged PCA on a segmented time series data set according to aspects of the present disclosure. As we can see from the confusion matrices, the number of required input variables is at least 4 to get accurate models. The change of C values does not affect the performance of the classifier when 6-d space is used.

At this point, while we have presented this disclosure using some specific examples, those skilled in the art will recognize that our teachings are not so limited. Accordingly, this disclosure should be only limited by the scope of the claims attached hereto.

1. A method for identifying false transformer humming using machine learning, the method comprising:
providing a distributed fiber optic sensing system (DFOS), said system including a length of optical sensor fiber; and
a DFOS interrogator and analyzer in optical communication with the length of optical fiber, said DFOS interrogator configured to generate optical pulses from laser light, introduce the pulses into the optical fiber and detect/receive reflected signals from the optical fiber, said analyzer configured to analyze the reflected signals to generate time series data from the analyzed reflected signals;
operating the DFOS system while collecting the time series data and processing the data by
scaling and standardizing the time series data;
applying multiple bandpass filters (BPF) to obtain a signal at a center frequency f0 of 30 nHz where n=0, 1, 2, 3, . . . , and a lower cutoff frequency fi and higher cutoff frequency fh are set to 5 Hz and f0+5 Hz respectively;
segmenting the signal into signals having a shorter length;
downsampling the shorter length signals;
performing a principal component analysis on each of the segmented signals to convert data from feature space into a reduced space; and
classifying data files using a support vector machine to generate models of transformer hum of electrical transformers located proximate to the length of optical sensor fiber;
operating the DFOS system while collecting time series data;
preprocessing the collected time series data;
processing the data according to the above; and
generating a prediction for transformer hum using the generated models; and
outputting an indicia of the transformer hum prediction so generated.
